(19) United States
(12) Patent Application Publication
(10) Pub. No.: US 2013/0206056 A1
(43) Pub. Date: Aug. 15, 2013

(54) METHODS OF PRODUCING CRYSTALLINE SEMICONDUCTOR MATERIALS

(71) Applicants: Uwe Kerat, Baiersbronn (DE); Christian Schmid, Freudenstadt (DE); Jochem Hahn, Rottenburg (DE)

(72) Inventors: Uwe Kerat, Baiersbronn (DE); Christian Schmid, Freudenstadt (DE); Jochem Hahn, Rottenburg (DE)

(73) Assignee: SCHMID SILICON TECHNOLOGY GMBH, Freudenstadt (DE)

(21) Appl. No.: 13/640,121

(22) PCT Filed: Apr. 11, 2011
(86) PCT No.: PCT/EP2011/055636

§ 371 Date: Jan. 28, 2013

(30) Foreign Application Priority Data
Apr. 13, 2010 (DE) 10 2010 015 354.0

(51) Int. Cl. C30B 11/02; C30B 15/02; C30B 11/00; C30B 11/08

(52) U.S. Cl. CPC C30B 11/02; C30B 11/08; C30B 15/02; C30B 11/007; C30B 11/001
USPC 117/13; 117/81; 117/77; 117/83

(57) ABSTRACT

A method of producing a crystalline semiconductor material includes feeding particles of the semiconductor material and/or a precursor compound of the semiconductor material into a gas flow, wherein the gas flow has a sufficiently high temperature to convert the particles of the semiconductor material from a solid into a liquid and/or gaseous state and/or to thermally decompose the precursor compound, condensing out and/or separating the liquid semiconductor material from the gas flow, and converting the liquid semiconductor material to a solid state with formation of mono- or polycrystalline crystal properties.

### RELATED APPLICATIONS

This is a §371 of International Application No. PCT/EP2011/055636, with an inter-national filing date of Apr. 11, 2011 (WO 2011/128296 A1, published Oct. 20, 2011), which is based on German Patent Application No. 10 2010 015 354.0, filed Apr. 13, 2010, the subject matter of which is incorporated by reference.

### TECHNICAL FIELD

This disclosure relates methods for producing a crystalline semiconductor material which is suitable, in particular, for use in photovoltaics and in microelectronics.

### BACKGROUND

Elemental silicon is used in different degrees of purity inter alia in photovoltaics (solar cells) and in microelectronics (semiconductors, computer chips). Accordingly, it is customary to classify elemental silicon on the basis of its degree of purity. A distinction is made, for example, between “electronic grade silicon” having a proportion of impurities in the ppt range and “solar grade silicon,” which is permitted to have a somewhat higher proportion of impurities.

In the production of solar grade silicon and electronic grade silicon, metallurgical silicon (generally 98-99% purity) is taken as a basis and purified by a multistage, complex method. Thus, it is possible, for example, to convert the metallurgical silicon to trichlorosilane in a fluidized bed reactor using hydrogen chloride. The trichlorosilane is subsequently disproportionated to form silicon tetrachloride and monosilane. The latter can be thermally decomposed into its constituents silicon and hydrogen. A corresponding method sequence is described in WO 2009/121558, for example.

The obtained silicon has very generally at least a sufficiently high purity to be classified as solar grade silicon. Even higher purities can be obtained, if appropriate, by downstream additional purification steps. In particular, purification by directional solidification and zone melting should be mentioned in this context. Furthermore, for many applications it is favorable or even necessary for the silicon generally obtained in polycrystalline fashion to be converted into monocrystalline silicon. Thus, solar cells composed of monocrystalline silicon have a generally significantly higher efficiency than solar cells composed of polycrystalline silicon. The conversion of polycrystalline silicon into monocrystalline silicon is generally effected by the melting of the polycrystalline silicon and subsequent crystallization in a monocrystalline structure with the aid of a seed crystal. Conventional methods for converting polysilicon into monocrystalline silicon are the Czochralski method and the vertical crucible-free float zone method with a freely floating melt.

Overall, the production of high-purity silicon or, if appropriate, high-purity monocrystalline silicon involves a very high expenditure of energy. This is characterized by a sequence of chemical processes and changes in state of matter. In this context, reference is made, for example, to WO 2009/121558 already mentioned. The silicon obtained in the multistage process described arises in a pyrolysis reactor in the form of solid rods which, if appropriate, have to be comminuted and melted again for subsequent further processing, for example, in a Czochralski method.

### SUMMARY

We provide a method of producing a crystalline semiconductor material including feeding particles of the semiconductor material and/or a precursor compound of the semiconductor material into a gas flow, wherein the gas flow has a sufficiently high temperature to convert the particles of the semiconductor material from a solid to a liquid and/or gaseous state and/or to thermally decompose the precursor compound, condensing out and/or separating the liquid semiconductor material from the gas flow, and converting the liquid semiconductor material to a solid state with formation of mono- or polycrystalline crystal properties.

### DETAILED DESCRIPTION

Our methods produce a crystalline semiconductor material, in particular crystalline silicon. The method comprises a plurality of steps, namely:

(1) Feeding particles of the semiconductor material or alternatively feeding a precursor compound of the semiconductor material into a gas flow, wherein the gas flow has a sufficiently high temperature to convert the particles of the semiconductor material from the solid to the liquid and/or gaseous state and/or to thermally decompose the precursor compound. If appropriate, both particles of the semiconductor material and a precursor compound of the semiconductor material can be fed into the gas flow.

The particles of the semiconductor material are, in particular, metallic silicon particles such as can be obtained in large amounts, e.g., when silicon blocks are sawed to form thin wafer slices composed of silicon. Under certain circumstances, the particles can be at least slightly oxidized superficially, but they preferably consist of metallic silicon.

The precursor compound of the semiconductor material is preferably a silicon-hydrogen compound, particularly preferably monosilane (SiH₄). However, by way of example, the decomposition of chlorosilanes such as, e.g., trichlorosilane (SiHCl₃), in particular, is also possible.

The gas flow into which the particles of the semiconductor material and/or the precursor compound of the semiconductor material are fed generally comprises at least one carrier gas and, preferably, it consists of such a gas. An appropriate carrier gas is, in particular, hydrogen, which is advantageous particularly when the precursor compound is a silicon-hydrogen compound. Further preferably, the carrier gas can also be a carrier gas mixture of hydrogen and a noble gas, in particular argon. The noble gas is contained in the carrier gas mixture preferably in a proportion of 1% to 50%.

Preferably, the gas flow has a temperature of 500 to 5000° C., preferably 1000 to 5000° C., particularly preferably 2000 to 4000° C. At such a temperature, first, e.g., particles of silicon can be liquefied or even at least partly evaporated in the gas flow. Silicon-hydrogen compounds, too, are generally readily decomposed at such temperatures.

Particularly preferably, the gas flow is a plasma, in particular a hydrogen plasma. As is known, a plasma is a partly ionized gas containing an appreciable proportion of free charge carriers such as ions or electrons. A plasma is always obtained by external energy supply, which can be effected, in particular, by a thermal excitation, by radiation excitation or by excitations by electrostatic or electromagnetic fields. The latter excitation method, in particular, is preferred. Corresponding plasma generators are commercially available and need not be further explained.

(2) After feeding particles of the semiconductor material and/or the precursor compound of the semiconductor material into the gas flow, condensing out and/or separating liquid semiconductor material from the gas flow. For this purpose, preferably, use is made of a reactor container into which the gas flow with the particles of the semiconductor material and/or precursor compound of the semiconductor material or with corresponding subsequent products is introduced. Such a reactor container serves to collect and, if appropriate, condense the liquid and/or gaseous semiconductor material. In particular, it is provided to separate the mixture of carrier gas, semiconductor material (liquid and/or gaseous) and, if appropriate, gaseous decomposition products, the mixture arising in the context of our method. Following the process of feeding the particles of the semiconductor material and/or the precursor compound of the semiconductor material into the gas flow, the latter no longer comprises only a corresponding carrier gas, but also further constituents as well.

The reactor generally comprises a heat-resistant interior. It is generally lined with corresponding materials resistant to high temperatures so that it is not destroyed by the highly heated gas flow. By way of example, linings based on graphite or Si₃N₄ are suitable. Suitable materials resistant to high temperature are known.

Within the reactor, in particular the question of the transition of vapors formed, if appropriate, such as silicon vapors, into the liquid phase is of great importance. The temperature of the inner walls of the reactor is, of course, an important factor in this respect. Therefore, it is generally above the melting point and below the boiling point of silicon. Preferably, the temperature of the walls is kept at a relatively low level (preferably 1420° C. to 1800° C., in particular 1500° C. to 1600° C.). The reactor can have suitable insulating, heating and/or cooling media for this purpose.

Liquid semiconductor material should be able to collect at the bottom of the reactor. For this purpose, the bottom of the interior of the reactor can be embodied in conical fashion with an outlet at the deepest point to facilitate discharge of the liquid semiconductor material. The liquid semiconductor material should ideally be discharged in batch mode or continuously. The reactor correspondingly preferably has an outlet suitable for this purpose. Furthermore, of course, the gas introduced into the reactor also has to be discharged again. Besides a supply line for the gas flow, a corresponding discharge line is generally provided for this purpose.

The gas flow is preferably introduced into the reactor at relatively high speeds to ensure good swirling within the reactor. Preferably, a pressure slightly above standard pressure, in particular 1013 to 2000 mbar, prevails in the reactor.

Preferably, at least one section of the interior of the reactor is substantially cylindrical. The gas flow can be introduced via a channel leading into the interior. The opening of the channel is arranged particularly in the upper region of the interior, preferably at the upper end of the substantially cylindrical section.

With regard to preferred characteristics of the gas flow and the reactor, reference is made in particular to PCT/EP2009/008457, the subject matter of which is incorporated herein by reference.

(3) In a final step, the liquid semiconductor material converts to the solid state with formation of mono- or polycrystalline crystal structures.

Some particularly preferred methods which lead to the formation of the mono- or polycrystalline crystal structures mentioned are explained below. What is common to all these methods is that, in a conventional method, solid semiconductor material as starting material is taken as a basis, which material correspondingly has to be melted in a first step. This step can be omitted in the context of our methods. Our semiconductor material ultimately arises in liquid form directly or, if appropriate, after corresponding condensation. Our methods thus afford major advantages over conventional methods in particular from an energy standpoint.

### EXAMPLE 1

Particularly preferably, a melt is fed with the liquid semiconductor material, a single crystal of the semiconductor material, in particular a silicon single crystal, being pulled from the melt. Such a procedure is also known as the Czochralski method or as a crucible pulling method or as pulling from the melt. In general, in this case the substance to be crystallized is held in a crucible just above its melting point. A small single crystal of the substance to be grown is dipped as a seed into the melt and subsequently pulled slowly upwardly with rotation, without contact with the melt being broken in the process. In this case, the solidifying material takes on the structure of the seed and grows into a large single crystal.

In the context of our methods, such a crucible is then fed with the liquid semiconductor material condensed out and/or separated from the gas flow in step (2). Monocrystalline semiconductor rods of any desired length can be pulled.

### EXAMPLE 2

Further particularly preferably, the liquid semiconductor material from step (2) is subjected to directional solidification. With regard to suitable preliminary steps for carrying out directional solidification, reference is made, for example, to DE 10 2006 027 273 and DE 29 33 164, the subject matter of both hereby incorporated by reference. Thus, the liquid semiconductor material can be transferred into a melting crucible, for example, which is slowly lowered from a heating zone. In general, impurities accumulate in the finally solidifying part of a semiconductor block thus produced. This part can be mechanically separated and, if appropriate, be introduced into the production process again in an earlier stage of the method.

### EXAMPLE 3

Also particularly preferably, the liquid semiconductor material from step (2) is processed in a continuous casting method.

In such a method, liquid semiconductor materials such as silicon can be solidified unidirectionally, polycrystalline structures generally being formed. In this case, use is usually made of a bottomless crucible as illustrated, for example, in FIG. 1 of DE 600 37 944. The crucible is traditionally fed with solid semiconductor particles melted by heating media and generally an induction heating system. Slowly lowering the semiconductor melt from the heating region results in solidification of the melted semiconductor and, in the process, formation of the polycrystalline structures. A strand of solidified polycrystalline semiconductor material arises, from which segments can be separated and processed further to form wafers.

Our method affords the striking advantage that melting of solid silicon in the bottomless crucible can be completely omitted. Instead, the silicon is transferred into the crucible in liquid form. The method implementation can thus be considerably simplified, and the apparatus outlay also proves to be significantly lower. Quite apart from that, of course, the procedure affords considerable advantages from an energy standpoint.

### EXAMPLE 4

Still further particularly preferably, a melt arranged in a heating zone is fed with the liquid semiconductor material. The melt is cooled by lowering and/or raising the heating zone such that, at its lower end, a solidification front forms along which the semiconductor material crystallizes.

In known vertical crucible-free float zone methods, a rod composed of semiconductor material having a polycrystalline crystal structure is usually provided in a protective gas atmosphere and, generally at its lower end, melted by an induction heating system. In this case, only a relatively narrow zone is ever transferred into the melt. The rod rotates slowly so that this takes place as uniformly as possible. The melted zone is in turn brought into contact with a seed crystal, which usually rotates in the opposite direction. In this case, a so-called “freely floating zone” is established, a melt, which is kept stable principally by surface tension. This melting zone is then moved slowly through the rod, which can be done by the abovementioned lowering of the rod together with the melt or alternatively by raising the heating zone. The melt that emerges from the heating zone and subsequently cools solidifies while maintaining the crystal structure predefined by the seed crystal, that is to say that a single crystal is formed. By contrast, impurity atoms segregate to the greatest possible extent into the melting zone and are thus bound in the end zone of the single crystal after the conclusion of the method. The end zone can be separated. A description of such a method and of a device suitable therefor is found, e.g., in DE 60 2004 001 510 T2.

By feeding the “freely floating zone” with liquid silicon from step (2) in accordance with our method, this procedure can be significantly simplified. The melting of solid silicon can be completely omitted since, after all, liquid silicon is provided from the plasma reactor. Otherwise, however, the known procedure can be left unchanged.

Float zone methods make it possible to produce extremely high-quality silicon single crystals since the melt itself is supported without contact and, consequently, does not come into contact at all with sources of potential contaminants, e.g., crucible walls. In this respect, a float zone method is distinctly superior to a Czochralski method, for example.

In all four examples above it is necessary to transfer the liquid semiconductor material from step (2) from the plasma reactor into a corresponding device in which the transition of the liquid semiconductor material to the solid state with formation of mono- or polycrystalline crystal structures then takes place. Such a device is, in the case of Example 1, e.g., the crucible from which the single crystal of the semiconductor material is pulled, and, in the case of Example 4, a device with the melt arranged in the heating zone. The liquid semiconductor material can be transferred, e.g., by grooves and/or pipes, which can be produced from quartz, graphite or silicon nitride, for example. If appropriate, heating units can be assigned to these transfer means to prevent the liquid semiconductor material from solidifying during transport. The coupling of the transfer means to the reactor container in which the liquid semiconductor material is condensed out and/or separated from the gas flow can be effected by a siphon-like pipe connection, for example. Liquid semiconductor material can be produced as required in the reactor container by corresponding variation of the quantity of particles of the semiconductor material and/or the precursor compound of the semiconductor material which is fed into the highly heated gas flow. The liquid semiconductor material that arises collects in the reactor container and produces a corresponding hydrostatic pressure. With the siphon-like pipe connection, in a manner governed by the pressure, liquid semiconductor material can, in a controlled manner, be discharged from the reactor container and fed to the device in which the transition of the liquid semiconductor material to the solid state with formation of mono- or polycrystalline crystal structures then takes place.

1. A method of producing a crystalline semiconductor material comprising:
feeding particles of the semiconductor material and/or a precursor compound of the semiconductor material into a gas flow, wherein the gas flow has a sufficiently high temperature to convert the particles of the semiconductor material from a solid to
a liquid and/or gaseous state and/or to thermally decompose the precursor compound,
condensing out and/or separating the liquid semiconductor material from the gas flow, and
converting the liquid semiconductor material to a solid state with formation of mono- or polycrystalline crystal properties.

2. The method according to claim 1, wherein a melt is fed with the liquid semiconductor material and a single crystal of the semiconductor material is pulled from said melt.

3. The method according to claim 1, wherein the liquid semiconductor material is subjected to directional solidification.

4. The method according to claim 1, wherein the liquid semiconductor material is processed in a continuous casting method.

5. The method according to claim 1, wherein a melt arranged in a eating zone is fed with the liquid semiconductor material, said melt being cooled by inhernt lowering and/or by raising of the heating zone such that, at its lower end, a solidification front forms along which the semiconductor material crystallizes in a monocrystalline structure.
